(19) United States
(12) Patent Application Publication
(10) Pub. No.: US 2024/0306510 A1
(43) Pub. Date: Sep. 12, 2024

(54) CONTROL DEVICE FOR REDUCING A DELAY OF THE RELATIVE MOVEMENT OF THE VIBRATING BODY AND THE CONTACTING BODY

(71) Applicant: CANON KABUSHIKI KAISHA, Tokyo (JP)

(72) Inventors: HIROMITSU MORITA, Saitama (JP); AKIO ATSUTA, Kanagawa (JP)

(21) Appl. No.: 18/595,080

(22) Filed: Mar. 4, 2024

(30) Foreign Application Priority Data
Mar. 9, 2023 (JP) 2023-036395

(51) Int. Cl. H10N 30/80; H10N 30/20

(52) U.S. Cl. CPC H10N 30/802; H10N 30/20

(57) ABSTRACT

A control device controls driving of a vibration actuator that moves a vibrating body and a contacting body in contact with the vibrating body relative to each other by vibration of the vibrating body excited when a plurality of signals having a phase difference are applied to an electromechanical energy conversion element. The control device includes a first control unit that controls the phase difference between the signals to a first phase difference when the vibrating body and the contacting body do not move relatively and starts moving the vibrating body and the contacting body relatively. The first phase difference is such that the positive/negative sign of the relative position or the relative speed of the vibrating body and the contacting body immediately after the vibrating body and the contacting body start moving relatively is not opposite to the positive/negative sign of the target position or the target speed.

### BACKGROUND

### Field of the Invention

The present disclosure relates to a control device, an electronic device, a method for controlling the control device, and a storage medium storing a program.

### Description of the Related Art

Some existing vibration actuators cause a vibrating body to be in pressure contact with a driven body and relatively move the vibrating body and the driven body by vibration excited in the vibrating body. To control the driving of the vibration actuators, frequency phase difference control has been developed in which the frequency of 2-phase drive signals is changed for a high speed side, and the phase difference between the 2-phase drive signals is changed for the low-speed side.

However, in a phase difference region around 0° or 180°, the drive state becomes unstable, and a generated driving force decreases, resulting in a so-called speed dead zone where movement stops. The dead zone may cause a delay of the start-up of the vibration actuator. A technique has been proposed to improve the responsiveness in control performed by drive mechanisms using such vibration actuators.

For example, to improve the startability of the vibration actuator, Japanese Patent Laid-Open No. 2017-123708 describes a method for setting the phase difference at the boundary of the speed dead zone as an initial phase difference and performing phase difference control from the initial phase difference at the start of driving.

However, when an object with large inertia, such as a high-magnification zoom lens barrel, is driven, the object may move in a direction opposite the driving direction at, for example, the beginning and end of the movement at which the phase difference is small and, thus, the feed vibration, which is the driving force in the driving direction, is low.

### SUMMARY

The present disclosure reduces a delay of the relative movement of the vibrating body and the contacting body.

According to an aspect of the present disclosure, a control device is provided that controls driving of a vibration actuator configured to move a vibrating body and a contacting body in contact with the vibrating body relative to each other by vibration of the vibrating body excited when a plurality of signals having a phase difference are applied to an electromechanical energy conversion element. The device includes a first control unit configured to control the phase difference between the plurality of signals to a first phase difference in a first period from when the vibrating body and the contacting body do not move relative to each other to when the vibrating body and the contacting body start moving relative to each other, a second control unit configured to control the phase difference between the plurality of signals to transition from the first phase difference to a second phase difference having an absolute value that is less than an absolute value of the first phase difference in a second period after the vibrating body and the contacting body start moving relative to each other, and a third control unit configured to control the phase difference between the plurality of signals based on one of a relative position and a relative speed of the vibrating body and the contacting body and one of a target position and a target speed in a third period after the phase difference between the plurality of signals transitions to the second phase difference.

Further features of the present invention will become apparent from the following description of exemplary embodiments with reference to the attached drawings.

### BRIEF DESCRIPTION OF THE DRAWINGS

FIGS. 1A to 1D illustrate an example of the configuration of a vibration actuator.

FIGS. 2A to 2C illustrate the elliptical motion excited at the front end of a protruding portion that constitutes a vibrating body.

FIG. 3 is a block diagram of an example of the configuration of a vibration drive system.

FIGS. 4A and 4B illustrate the pulse widths of pulse signals output from an AC signal generating unit.

FIG. 5 illustrates the relationship among a phase difference, a pulse width, a frequency, and a driving speed.

FIG. 6 is a flowchart of a driving method.

FIG. 7 illustrates an example of the direction of movement with respect to the driving direction immediately after the start of relative movement.

FIGS. 8A and 8B illustrate the relationship among a phase difference, a pulse width, and the position of a vibration actuator.

FIGS. 9A and 9B are flowcharts of a driving method.

FIG. 10 is a perspective view of an example of the structure of a lens-driving mechanism unit.

FIG. 11 illustrates the relationship between the time and position at around the startup time.

### DESCRIPTION OF THE EMBODIMENTS

Exemplary embodiments are described in detail below with reference to the accompanying drawings. In the following description, a “vibration drive system” includes a “vibration actuator” and a “control device”. A “vibration actuator” includes a “vibrating body” and a “contacting body”. A “vibrating body” includes an “elastic body” and an “electromechanical energy conversion element”.

### First Embodiment

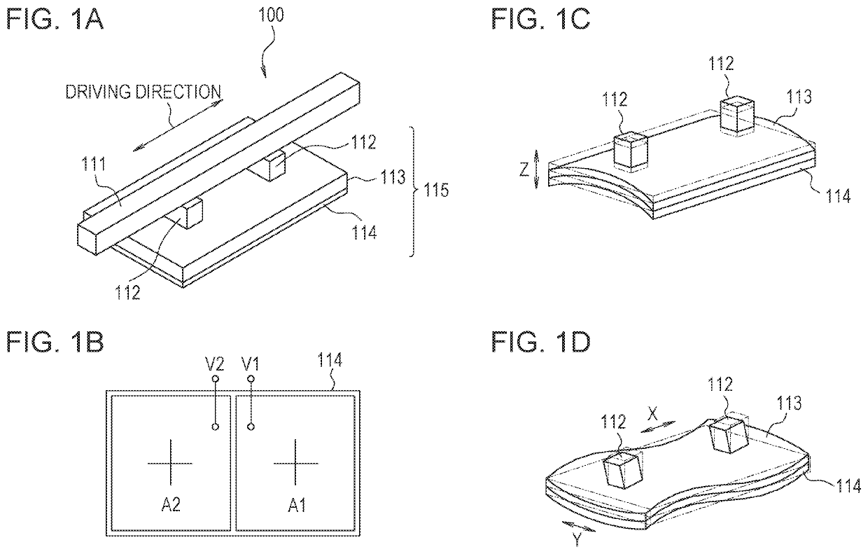

FIG. 1A is a perspective view of an example of the configuration of a vibration actuator 100 according to the first embodiment. The vibration actuator 100 includes a contacting body 111 and a vibrating body 115. The vibrating body 115 includes an elastic body 113 made of a flat, metallic material, a piezoelectric element 114, which is an electromechanical energy conversion element, bonded to one surface (a first surface) of the elastic body 113, and two protruding portions 112. The two protruding portions 112 are provided on the other surface of the elastic body 113 (a second surface opposite the first surface). The contacting body 111 and the two protruding portions 112 of the vibrating body 115 are in pressure contact with each other by a pressure-applying unit (not illustrated).

FIG. 1B is a plan view of an example of the structure of the piezoelectric element 114. FIG. 1C illustrates a first vibration mode (hereinafter referred to as a “mode A”) excited in the vibrating body 115. FIG. 1D illustrates a second vibration mode (hereinafter referred to as a “mode B”) excited in the vibrating body 115.

The direction between the two protruding portions 112 of the vibrating body 115 is defined as an X-direction, the thickness direction of the elastic body 113 as a Z-direction, and the direction orthogonal to the X- and Z-directions as a Y-direction. As illustrated in FIG. 1B, two electrodes A1 and A2 are formed on one surface of the piezoelectric element 114, which are two equal parts in the longer side direction (the X-direction). The polarization direction in each of the electrodes A1 and A2 is the same direction (+).

A common electrode (a full surface electrode) is formed on the other surface of the piezoelectric element 114. Of the two electrode regions of the piezoelectric element 114, an AC voltage V2 is applied to an electrode A2 (the left electrode in FIG. 1B), and an AC voltage V1 is applied to an electrode A1 (the right electrode in FIG. 1B). If the AC voltages V1 and V2 are AC voltages that have a frequency around the resonance frequency in mode A and that are in phase, the entire piezoelectric element 114 (the two electrode regions) expands at one instant and contracts at another instant. As a result, mode-A vibration illustrated in FIG. 1C occurs on the vibrating body 115.

If the AC voltages V1 and V2 are AC voltages that have a frequency around the resonance frequency in mode B and that are out of phase by 180°, the right electrode region of the piezoelectric element 114 in FIG. 1B contracts, and the left electrode region of the piezoelectric element 114 in FIG. 1B expands at one instant. At another instant, the relationship is reversed. As a result, as illustrated in FIG. 1D, mode-B vibration occurs on the vibrating body 115.

Mode A is a first-order out-of-plane bending vibration mode in which two nodes appear on the vibrating body 115 in substantially parallel to the X-direction. Mode B is a second-order out-of-plane bending vibration mode in which three nodes appear on the vibrating body 115 in substantially parallel to the Y-direction.

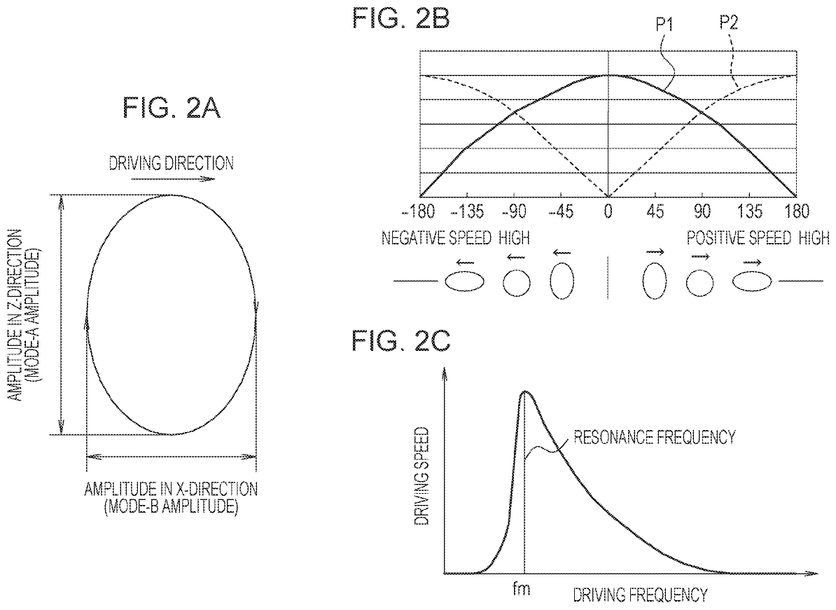

FIG. 2A illustrates elliptical vibration excited at the front end of the protruding portion 112. The protruding portion 112 is located near the antinode of the mode-A vibration and near the node of the mode-B vibration. Therefore, the front end of the protruding portion 112 reciprocates in the Z-direction by pendulum motion using the node of mode-A vibration as a fulcrum and also reciprocates in the X-direction by mode-B vibration.

Therefore, by simultaneously exciting and superimposing the mode-A and mode-B vibrations such that the phase difference between the vibrations is around +π/2, the elliptical motion of the front end surface of the protruding portion 112 can be generated in the XZ plane. At this time, since a friction force due to pressure contact is created between the two protruding portions 112 and the contacting body 111, the elliptical motion of the protruding portions 112 generates a driving force (a thrust force) that moves the vibrating body 115 and the contacting body 111 relatively in the X-direction.

That is, the protruding portion 112 functions as a drive unit to move the vibrating body 115 and the contacting body 111 relative to the contacting body 111. Hereafter, the ratio of the amplitude in the Z-direction to the amplitude in the X-direction of the elliptical motion generated at the front end of the protruding portion 112 in FIG. 2A is defined as the elliptical ratio of the elliptical motion. In the following description, the vibrating body 115 of the vibration actuator 100 is fixed so as to drive the contacting body 111 in the X-direction.

FIG. 2B illustrates the amplitudes in the first and second vibration modes when the phase difference between the 2-phase voltages V1 and V2 is varied from −180 degrees to 180 degrees.

When the phase difference between the 2-phase AC voltages V1 and V2 applied to the two electrodes A1 and A2, respectively, in the polarized piezoelectric element 114 is changed from −180 degrees to 180 degrees, an amplitude P1 in the first vibration mode and an amplitude P2 in the second vibration mode are changed as illustrated in FIG. 2B.

The axis of abscissae in FIG. 2B represents the phase difference, and the axis of ordinates represents the amplitudes in the first and second vibration modes. A combination of the first and second vibration modes excites elliptical motion of the protruding portion 112 and enables adjustment of the elliptical ratio of the excited elliptical motion of a predetermined one of the protruding portions 112 by changing the phase difference between the applied AC voltages V1 and V2.

The lower section of FIG. 2B illustrates the elliptical shape according to the phase difference along the axis of abscissae. By reversing the positive/negative sign of the phase difference between the AC voltages V1 and V2, the driving direction of the linearly driving vibration actuator 100 can be switched. Furthermore, by continuously changing the phase difference from any value including a positive/negative sign (for example, continuously changing the phase difference from +90 degrees to −90 degrees), the driving direction and the speed can be continuously changed.

FIG. 2C illustrates the relationship between the driving frequency of the vibration actuator 100 and the driving speed (the relative moving speed between the vibrating body 115 and the contacting body 111). The driving speed is maximized when the vibration actuator 100 is driven at the resonance frequency fm, decreases gradually from the resonance frequency fm toward higher frequencies, and decreases abruptly from the resonance frequency fm toward lower frequencies.

Therefore, by changing the driving frequency of the piezoelectric element 114, the magnitude of the elliptical vibration can be changed while maintaining the elliptical ratio. For example, by bringing the driving frequency closer to the resonance frequency fm of the vibration actuator 100, the elliptical vibration can be increased and, thus, the driving speed can be increased. In addition, by increasing or decreasing the driving frequency of the applied AC voltage from the resonance frequency fm of the vibration actuator 100, the elliptical vibration can be reduced and, thus, the driving speed can be reduced.

The driving speed can also be controlled by fixing the driving frequency and changing the elliptical ratio as illustrated in FIG. 2B. As described above, a wide range of the speed from low to high can be controlled by changing the magnitude of elliptical vibration and the elliptical ratio using the driving frequency and phase difference.

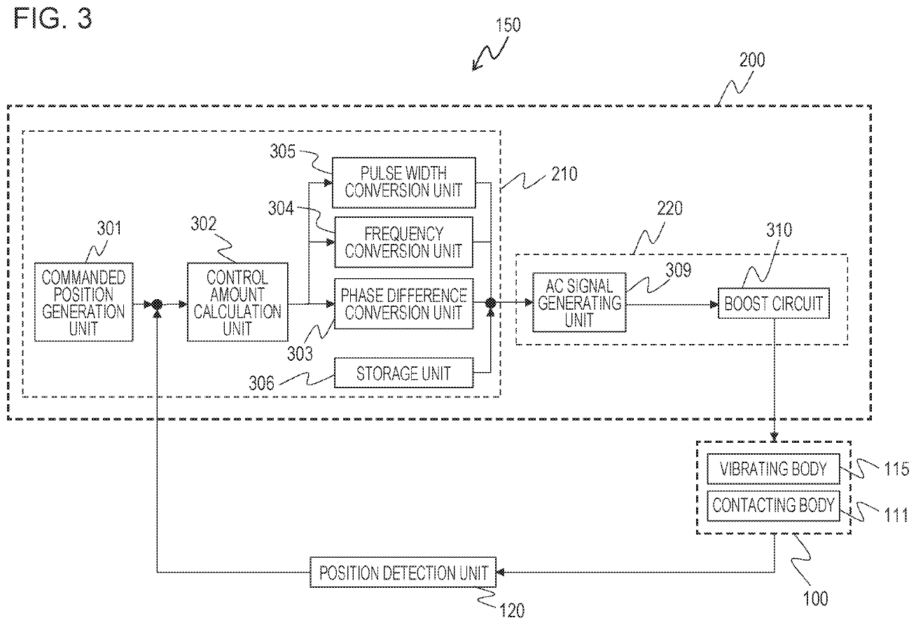

FIG. 3 is a block diagram of an example of the configuration of the vibration drive system 150. The vibration drive system 150 includes a control device 200. The control device 200 simultaneously drives and controls the vibration actuator 100. Since the vibration actuator 100 (the vibrating body 115 and the contacting body 111) has already been described with reference to FIGS. 1A to 1D, description of the vibration actuator 100 is omitted.

The vibration drive system 150 includes the control device 200, the vibration actuator 100, and a position detection unit 120. The control device 200 includes a control unit 210 and a drive unit 220. The control unit 210 outputs a control signal to control the driving of the vibration actuator 100. The drive unit 220 outputs an AC signal serving as a drive signal to drive the vibration actuator 100 on the basis of the control signal output from the control unit 210.

The control unit 210 includes a commanded position generation unit 301, a control amount calculation unit 302, a phase difference conversion unit 303, a frequency conversion unit 304, a pulse width conversion unit 305, and a storage unit 306. The drive unit 220 includes an AC signal generating unit 309 and a boost circuit 310. Each of the units constituting the control unit 210 performs a specific operation in accordance with an output (a control signal). The control unit 210 is a widely used microcomputer and includes electrical components, such as an arithmetic unit (a central processing unit (CPU)), a memory that stores a program, and a memory serving as a working area into which the program is loaded. The control unit 210 generates a signal including information for controlling the driving of the vibration actuator 100.

The position detection unit 120 is, for example, an encoder and detects the position of the contacting body 111. The commanded position generation unit 301 generates a commanded position for moving the contacting body 111. A signal regarding the deviation between the commanded position, which is the output of the commanded position generator 301, and the output of the position detection unit 120 is input to the control amount calculation unit 302. As used herein, the term “commanded position” refers to a target position that varies with time. The commanded position is set to perform position control to move the contacting body 111 to the final stop position.

For example, the commanded position is set from a combination of an acceleration period in which the driving speed of the vibrating body 115 (the speed of movement of the contacting body) is accelerated, a constant speed period in which the driving speed is maintained, and a deceleration period in which the driving speed is decelerated. However, the combination is not limited thereto and may be a combination of the acceleration and deceleration periods.

The control amount calculation unit 302 calculates the control amount of the vibrating body 115. The control amount output from the control amount calculation unit 302 is input to the phase difference conversion unit 303. The phase difference conversion unit 303 converts the control amount obtained from the control amount calculation unit 302 into a phase difference and determines the elliptical ratio of the elliptical motion to be excited on the protruding portion 112 of the vibrating body 115. The phase difference converted by the phase difference conversion unit 303 is the phase difference between the AC voltages V1 and V2 applied to the piezoelectric element 114. A threshold value is set for the phase difference. If the phase difference is outside the range of the threshold value, the phase difference is set to the threshold value. The threshold value is set in the range of ±90 degrees, for example. However, the threshold value is not limited thereto and may be in the other range, such as ±70 degrees or ±110 degrees.

The frequency conversion unit 304 converts the control amount obtained from the control amount calculation unit 302 into a frequency and determines the size of the ellipse of the elliptical motion to be excited on the protruding portion 112 of the vibrating body 115. The pulse width conversion unit 305 converts the control amount obtained from the control amount calculation unit 302 into a pulse width and determines the size of the ellipse of the elliptical motion to be excited on the protruding portion 112 of the vibrating body 115.

The storage unit 306 stores table data prepared in accordance with previously measured temperatures, postures, and the like and outputs a set signal for the phase difference set at the start of driving. The control signals output from the phase difference conversion unit 303, frequency conversion unit 304, and pulse width conversion unit 305 and a phase difference set signal from the storage unit 306 are input to the AC signal generating unit 309.

The AC signal generating unit 309 is, for example, a driver circuit that generates an AC signal by a switching operation. The output of the AC signal generating unit 309 is input to the boost circuit 310. The boost circuit 310 has, for example, a configuration with a coil and a transformer. However, the configuration is not limited thereto and may have a configuration with only one of a coil and a transformer. The boost circuit 310 boosts each of the 2-phase AC signals generated by the switching operation in the AC signal generating unit 309 and applies the AC signals to the electrodes of the piezoelectric element 114.

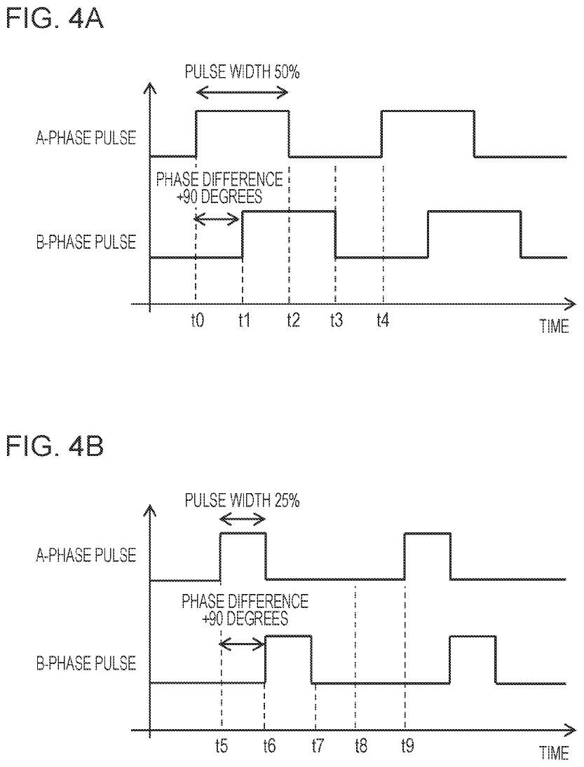

The pulse widths of the 2-phase AC signals output from the AC signal generating unit 309 are described below with reference to FIGS. 4A and 4B. FIG. 4A illustrates the time change in the phase A and B pulse signals when the pulse width is 50% of the cycle length. The phase A pulse signal and phase B pulse signal are the 2-phase AC signals output from the AC signal generating unit 309. The voltages V1 and V2 are the boosted phase A and B pulse signals, respectively. The time period between time t0 and t4 is one cycle length of the driving frequency that drives the vibration actuator 100, and the phase A and B pulse signals are high-level pulse signals that are output for a time period that is equal to 50% of the cycle length. When the phase difference between the phase A and B pulse signals is +90 degrees, the phase A and B pulse signals are output so that their rising edges are shifted by ¼ cycle length (at time t0 and time t1).

FIG. 4B illustrates the time change in the phase A and B pulse signals when the pulse width is 25% of the cycle. The time period from time t5 to t9 is one cycle length of the driving frequency that drives the vibration actuator 100, and the phase A and B pulse signals are high-level pulse signal output for a time period that is equal to 25% of the cycle length. When the phase difference between the phase A and B pulse signals is +90 degrees, the phase A and B pulse signals are output so that their rising edges are shifted by ¼ cycle length (at time t5 and time t6).

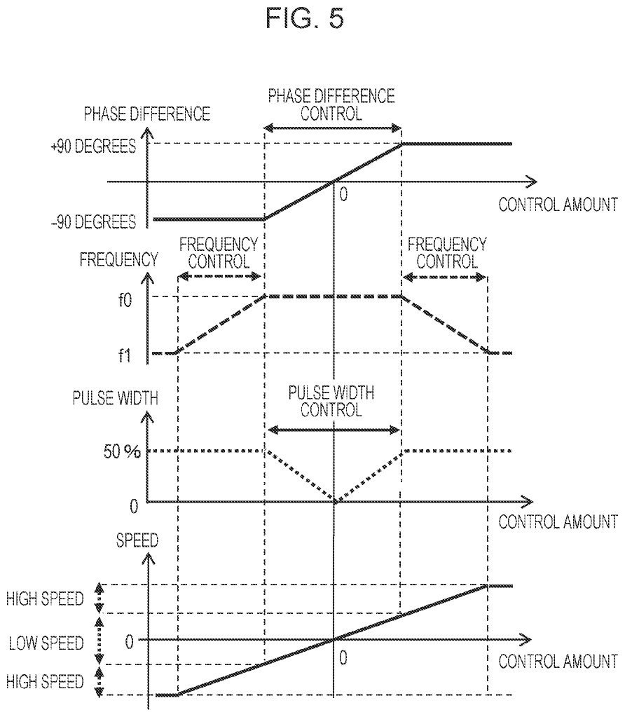

The relationship among the control amount output from the control amount calculation unit 302, the output from the control unit 210, and the speed of the contacting body 111 is described below with reference to FIG. 5. FIG. 5 illustrates the relationship among the phase difference, pulse width, frequency, and speed with respect to the control amount output from the control amount calculation unit 302. In a zone where the absolute value of the control amount is small and the speed is low, the phase difference, pulse width, and frequency are controlled so that the phase difference and the pulse width vary (the phase difference control and pulse width control). In a zone where the absolute value of the control amount is large and the speed is high, the frequency, phase difference, and pulse width are controlled so that the frequency varies (the frequency control). The relationship between frequencies f0 and f1 illustrated in FIG. 5 is f0>f1. That is, the configuration is such that driving using the phase difference and pulse width and driving using the frequency are switched in accordance with the control amount. While the description above has been made with reference to a technique for simultaneously changing both the phase difference and pulse width, one of the phase difference and pulse width may be fixed, and the other may be changed.

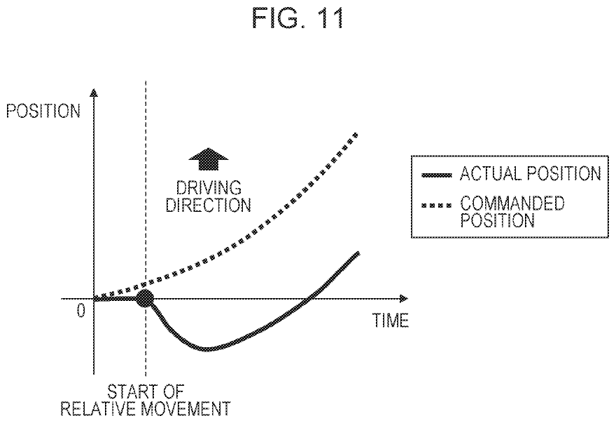

When an object with large inertia, such as a high-magnification zoom lens barrel, is driven, the object may move in a direction opposite the driving direction at, for example, the beginning and end of the movement at which the phase difference is small and, thus, the feed vibration, which is the driving force in the driving direction, is low. For example, as illustrated in FIG. 11, although the commanded position denoted by the dotted line indicates the positive direction as the driving direction, the actual position of the vibration actuator 100 denoted by the solid line moves in the negative direction (the opposite direction) after the start of relative movement, which phenomenon causes a delay in drive.

The present embodiment provides a vibration actuator 100 capable of reducing the above-described phenomenon even when the vibration actuator 100 is used to drive an object with large inertia.

In the vibration actuator 100, the vibrating body 115 and the contacting body 111 that is in contact with the vibrating body 115 are moved relative to each other by vibration of the vibrating body 115, which is excited by application of a plurality of AC signals having phase differences to the piezoelectric element 114. The control device 200 controls the driving of the vibration actuator 100.

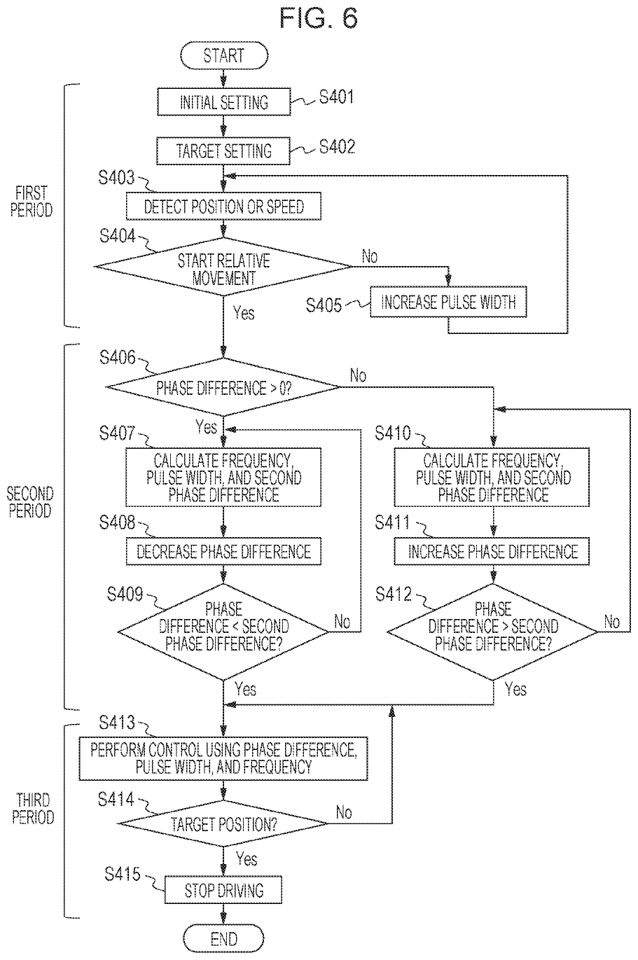

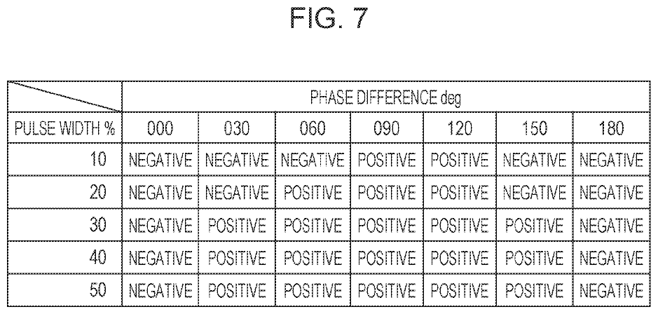

The control operation performed by the vibration drive system 150 is described below with reference to FIGS. 6 and 7.

FIG. 6 is a flowchart of the control method for use of the control device 200 of the vibration actuator 100 according to the first embodiment. As described above, the control unit 210 includes a CPU, a memory, and the like. Each of processes in the flowchart illustrated in FIG. 6 is performed by the CPU that loads a predetermined program stored in the memory and controls the operations performed by the units of the control device 200. FIG. 7 illustrates an example of the direction of movement with respect to the driving direction of the vibration actuator 100 immediately after the start of relative movement by the vibration actuator 100 in accordance with the pulse width (the vertical axis) and phase difference (the horizontal axis) applied to the vibration actuator 100.

In step S401, when driving is started, the control unit 210 performs control so that, as initial setting, the phase difference between the 2-phase AC signals is set to a first phase difference, the frequency of the 2-phase AC signals to a starting frequency, and the pulse width of the 2-phase AC signals to a starting pulse width. As a result, the phase difference between the AC voltages V1 and V2 applied to the piezoelectric element 114 is the first phase difference.

An example in which the control unit 210 controls the phase difference, frequency, and pulse width of the 2-phase AC signal is described below. However, the amplitude may be controlled instead of the pulse width.

The first phase difference is a phase difference for which no phenomenon of the movement in a direction opposite the driving direction occurs immediately after the start of relative movement. That is, the first phase difference is such that the positive/negative sign of the relative position or relative speed of the vibrating body 115 and the contacting body 111 is not opposite to the positive/negative sign of the target position or target speed immediately after the vibrating body 115 and the contacting body 111 start relative movement. The first phase difference is a phase difference within the range of phase differences each corresponding to “positive” in FIG. 7.

For example, FIG. 7 illustrates the relationship between the pulse width and the phase difference for the vibration actuator 100 measured and stored in the storage unit 306 in advance. In FIG. 7, “positive” indicates the relationship between the phase difference and the pulse width that causes movement in the positive driving direction, and “negative” indicates the relationship that causes movement in the negative driving direction.

As used herein, regarding the above-described relationships marked as “negative”, the term “first phase difference zone” refers to a phase difference zone in which the amplitude in the direction that intersects the driving direction is greater than the amplitude in the direction horizontal to the driving direction. The term “first value” refers to the upper limit of the first phase difference zone. The term “second phase difference zone” refers to a phase difference zone in which the amplitude in the direction horizontal to the driving direction is greater than the amplitude in the direction that intersects the driving direction. The term “second value” refers to the lower limit of the second phase difference zone. Then, a phase difference that is greater than the first value and less than the second value is set as a first phase difference. In the present example, the first value is 60°, and the second value is 150°. The first phase difference zone is, for example, 0° to 90°, and the second phase difference zone is, for example, 90° to 180°.

The “positive” in FIG. 7 indicates the phase difference for which the positive/negative sign of the relative position or relative speed of the vibrating body 115 and the contacting body 111 immediately after the vibrating body 115 and the contacting body 111 start moving relative to each other is not opposite to the positive/negative sign of the target position or target speed. The “negative” in FIG. 7 indicates the phase difference for which the positive/negative sign of the relative position or relative speed of the vibrating body 115 and the contacting body 111 is opposite to the positive/negative sign of the target position or target speed immediately after the vibrating body 115 and the contacting body 111 start moving relative to each other.

Among the phase differences for which the above-described positive/negative signs are not opposite, the first phase difference is greater than the upper limit of the phase difference zone in which, regarding the elliptical motion of a contact portion (the protruding portion 112) of the vibrating body 115 illustrated in FIGS. 2A and 2B, the amplitude in the direction intersecting the driving direction is greater than the amplitude in the direction horizontal to the driving direction of the vibration actuator 100 and less than the lower limit of the phase difference zone in which the amplitude in the direction horizontal to the driving direction is greater than the amplitude in the direction intersecting the driving direction.

Alternatively, the first phase difference is set to, among the phase differences marked as “positive” in FIG. 7, a phase difference that is greater than or equal to the lower limit of the phase differences and less than or equal to the upper limit of the phase differences. The first phase difference is greater than or equal to the lower limit and less than or equal to the upper limit of the phase differences for which the above-described positive/negative signs are not opposite. In the present example, the lower limit of the phase differences is 90°, and the upper limit of the phase differences is 120°.

In the relationship between the phase difference that causes movement in the negative direction and the pulse width, the relative movement is in a direction opposite to the driving direction immediately after the start of the relative movement. However, as the relationship gets closer to the relationship between the phase difference that causes movement in the positive direction and the pulse width, the amount of movement in the opposite direction decreases. If this amount of movement is acceptable, the relationship between the phase difference that causes movement in the negative direction and the pulse width may be used.

In step S402, the control unit 210 sets a stop position, which is the final stop position, and one of a commanded position, which is the target position that changes with time on the basis of the stop position, and a commanded speed, which is the target speed. For example, the commanded position and speed are set at predetermined intervals (for example, every Δt) for each of the acceleration period to accelerate the vibration actuator 100, a constant speed period to maintain the vibration actuator 100 at the target speed, and a deceleration period to decelerate the vibration actuator 100. However, the commanded position and speed are not limited thereto. For example, the commanded position and speed may be set for an acceleration period and a deceleration period without a constant speed period, in accordance with the distance.

In step S403, the position detection unit 120 detects the relative position or relative speed of the contacting body 111 and the vibrating body 115.

In step S404, the control unit 210 determines whether the vibration actuator 100 has started the relative movement on the basis of the above-described change in the relative position or relative speed value. If the vibration actuator 100 has not started the relative movement, the processing proceeds to step S405. If the vibration actuator 100 has started the relative movement, the processing proceeds to step S406.

In step S405, the control unit 210 increases the pulse width of the 2-phase AC signals while keeping the phase difference between the 2-phase AC signals at the first phase difference. At this time, if the pulse width reaches a threshold value (for example, 50%), the control unit 210 may decrease the frequency of the 2-phase AC signals. The control unit 210 uses, as the amount of increase in the pulse width and the amount of decrease in frequency of the 2-phase AC signals, the values determined in accordance with the time period required to start the relative movement and the load condition. Thereafter, the processing returns to step S403, where steps S403 to S405 are repeated until the vibration actuator 100 starts the relative movement.

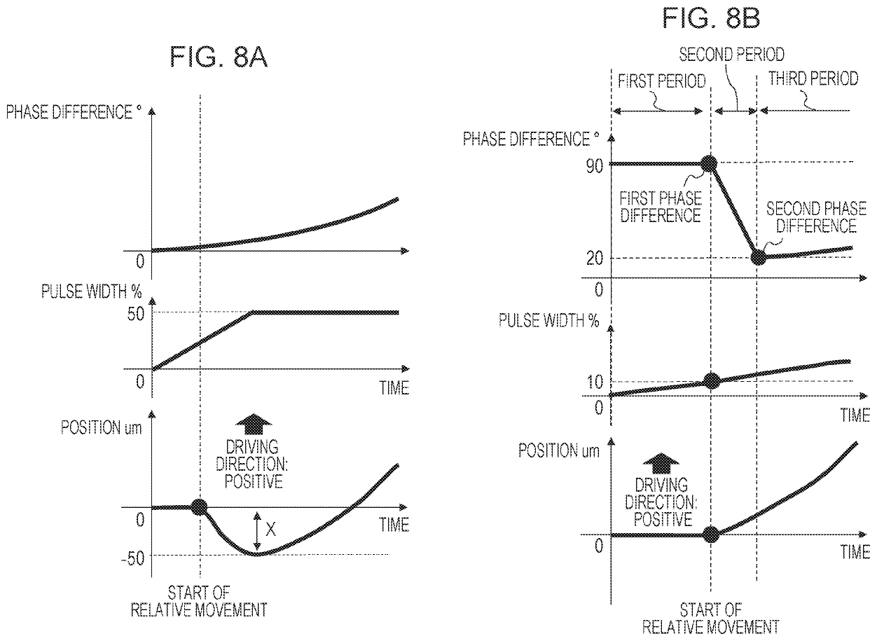

Steps S401 to S405 described above correspond to a first period illustrated in FIG. 8B. The first period is the time period from when the vibrating body 115 and the contacting body 111 are not moving relative to each other to when the vibrating body 115 and the contacting body 111 start moving. The control unit 210 controls the phase difference between the plurality of AC signals to the first phase difference in the first period. In addition, in the first period, the control unit 210 performs control to increase the pulse width (or the amplitude) of the plurality of AC signals until the vibrating body 115 and the contacting body 111 start moving relative to each other. That is, in the first period, the control unit 210 performs control so that the first phase difference is kept unchanged as the phase difference between the plurality of AC signals and, in addition, the pulse width (or the amplitude) of the plurality of AC signals is gradually increased. As described above, when the vibrating body 115 and the contacting body 111 are not moving relative to each other, the control unit 210 controls the phase difference between the plurality of AC signals to the first phase difference and controls the vibrating body 115 and the contacting body 111 to start moving relative to each other.

As illustrated in FIG. 7, the storage unit 306 stores the ranges of the phase difference and the pulse width (or the amplitude) for which the positive/negative sign of the relative position or relative speed immediately after the vibrating body 115 and the contacting body 111 start moving is not opposite the positive/negative sign of the target position or target speed. The control unit 210 sets the first phase difference on the basis of the range of the phase difference stored in the storage unit 306.

In step S401, when the vibrating body 115 and the contacting body 111 are not moving relative to each other, the control unit 210 performs control so that the phase difference between the plurality of AC signals is set to the first phase difference and, in addition, the pulse width (or amplitude) of the plurality of AC signals is set to a first pulse width (or a first amplitude) and causes the vibrating body 115 and the contacting body 111 to start moving relative to each other. The first phase difference and the first pulse width (or a first amplitude) are a phase difference and pulse width (or amplitude) for which the positive/negative sign of the relative position or relative speed of the vibrating body 115 and the contacting body 111 immediately after the vibrating body 115 and the contacting body 111 start moving relative to each other is not opposite to the positive/negative sign of the target position or target speed.

In step S406, the control unit 210 determines whether the first phase difference is positive after the start of relative movement of the vibration actuator 100. If positive, the processing proceeds to step S407. If not positive, the processing proceeds to step S410.

In step S407, the control unit 210 calculates the frequency and pulse width to be controlled on the basis of the commanded position or commanded speed described above and calculates the phase difference to be controlled as the second phase difference.

In step S408, the control unit 210 controls, as the phase difference between the 2-phase AC signals, the phase difference which is decreased from the first phase difference. As the amount of decrease in the phase difference, the value determined in accordance with the position, speed, and load conditions is used. At this time, the pulse width may be kept unchanged or may be varied so as to get closer to the pulse width controlled on the basis of the commanded position or commanded speed.

In step S409, the control unit 210 determines whether the phase difference between the 2-phase AC signals set in step S408 is less than the second phase difference. If the phase difference between the 2-phase AC signals is not less than the second phase difference, the processing returns to step S407, where steps S407 to S409 are repeated. If the phase difference between the 2-phase AC signals is less than the second phase difference, the processing proceeds to step S413.

In step S410, the control unit 210 calculates the frequency and pulse width to be controlled on the basis of the commanded position or commanded speed described above and calculates the phase difference to be controlled as the second phase difference.

In step S411, the control unit 210 sets a value increased from the first phase difference as the phase difference between the 2-phase AC signals. As the amount of increase in the phase difference, a value determined in accordance with the position, speed, and load conditions is used. At this time, the pulse width may be kept unchanged or may be varied to get closer to the pulse width controlled on the basis of the commanded position or commanded speed.

In step S412, the control unit 210 determines whether the phase difference between the 2-phase AC signals set in step S411 is greater than the second phase difference. If the phase difference between the 2-phase AC signals is not greater than the second phase difference, the processing returns to step S410, where steps S410 to S412 are repeated. If the phase difference between the 2-phase AC signals is greater than the second phase difference, the processing proceeds to step S413.

The steps S406 to S412 described above correspond to the second period illustrated in FIG. 8B. The second period is a period after the vibrating body 115 and the contacting body 111 start moving relative to each other. In the second period, the control unit 210 controls the phase difference between the plurality of AC signals so that the phase difference between the plurality of AC signals is changed from the first phase difference to the second phase difference having an absolute value that is less than the absolute value of the first phase difference. The second phase difference is the phase difference between the plurality of AC signals calculated in step 407 on the basis of one of the relative position and relative speed of the vibrating body 115 and the contacting body 111 and one of the target position and target speed.

In the case illustrated in FIG. 8B, in the second period, the control unit 210 controls the pulse width (or amplitude) of the plurality of AC signals so that the pulse width (or amplitude) of the plurality of AC signals gets closer to the calculated pulse width (or amplitude) of the plurality of AC signals on the basis of one of the relative position and relative speed of the vibrating body 115 and the contacting body 111 and one of the target position and target speed. In the second period, the control unit 210 may perform control so that the pulse width (or amplitude) of the plurality of AC signals is kept unchanged or increased.

In step S413, the control unit 210 controls the frequency, pulse width, and phase difference between the 2-phase AC signals on the basis of the commanded position or commanded speed described above.

In step S414, the control unit 210 determines whether the relative position of the contacting body 111 and the vibrating body 115 has reached the target position. If the target position has not been reached, the processing returns to step S413, where steps S413 and S414 are repeated. If the target position has been reached, the processing proceeds to step S415.

In step S415, the control unit 210 and drive unit 220 stop driving of the vibration actuator 100.

Steps S413 to S415 described above correspond to a third period illustrated in FIG. 8B. The third period is the period after the phase difference between the plurality of AC signals is changed to the second phase difference. In the third period, the control unit 210 controls the phase difference, pulse width (or amplitude), and frequency of the plurality of AC signals on the basis of one of the relative position and relative speed of the vibrating body 115 and the contacting body 111 and one of the target position and target speed.

As illustrated in FIG. 5, in the third period, when the phase difference between the plurality of AC signals reaches the upper or lower limit, the control unit 210 controls the frequency of the plurality of AC signals on the basis of one of the relative position and relative speed of the vibrating body 115 and the contacting body 111 and one of the target position and target speed. In addition, in the third period, if the pulse width (or amplitude) of the plurality of AC signals reaches the upper limit, the control unit 210 controls the frequency of the plurality of AC signals on the basis of one of the relative position and relative speed of the vibrating body 115 and the contacting body 111 and one of the target position and target speed.

The effects of the first embodiment are described below with reference to FIGS. 8A and 8B. FIG. 8A illustrates the case where a widely used control method is employed and illustrates the relationship among the phase difference, pulse width, and the position of the vibration actuator 100 when the driving direction is positive. FIG. 8B illustrates the case where the control method according to the first embodiment illustrated in FIG. 6 is employed and illustrates the relationship between the phase difference, pulse width, and the position of the vibration actuator 100 when the driving direction is positive. FIGS. 8A and 8B illustrate only the processing from the start of driving to the start and acceleration of relative movement, and description of the subsequent processing to the stoppage of driving is omitted.

As illustrated in FIG. 8A, according to the widely used control method, the phase difference is controlled based on the commanded position or commanded speed from when the driving starts, and the pulse width is gradually increased toward the upper limit (for example, 50%). In FIG. 8A, the state in which the position does not move from the start of driving to the start of relative movement corresponds to the dead zone described above. However, because the phase difference is small and, thus, the thrust-up vibration increases without much feed vibration that is the driving force in the driving direction, the position moves in the negative direction, which is the opposite direction of the driving direction, after start of relative movement, even though the driving direction is positive.

As compared with the original drive amount, an additional amount, that is, twice the above-described amount of movement in the opposite direction (“X” in FIG. 8A) is required, which causes a delay in drive.

In contrast, as illustrated in FIG. 8B, according to the control method of the first embodiment, the control device 200 increases the pulse width of the 2-phase AC signal while maintaining the above-described first phase difference in the first period until the start of relative movement. The first phase difference is, for example, 90°.

In the second period after the start of the relative movement, the control device 200 performs control using, as the phase difference between the 2-phase AC signals, a value decreased so that the first phase difference transitions to the above-described second phase difference.

The second phase difference is, for example, 20°. The decrease in phase difference continues until the phase difference between the 2-phase AC signals becomes less than the second phase difference and, thereafter, the third period starts. The pulse width here is varied so as to get closer to the value of the pulse width controlled on the basis of the commanded position or commanded speed in the third period. As described above, the pulse width is not limited thereto. The pulse width may be maintained at a value the same as the value immediately after the start of relative movement or may be increased.

In the third period, the control device 200 controls the frequency, pulse width, and phase difference between the 2-phase AC signals on the basis of the commanded position or commanded speed.

As described above, by increasing the thrust-up vibration when the phase difference is large and there is a large amount of feed vibration, which is the driving force in the driving direction, from the start of driving, the phenomenon of movement in the opposite direction immediately after the start of relative movement can be reduced, as indicated by the change in the position with time illustrated in FIG. 8B. This allows transition to the control using the frequency, pulse width, and phase difference between the 2-phase AC signal set on the basis of the commanded position or commanded speed while reducing the delay in drive.

In addition, according to the present embodiment, control is performed by using a pulse width. However, instead of a pulse width, voltage control that varies a switching voltage can provide the same effects.

As described above, according to the present embodiment, even when an object with large inertia is driven, the phenomenon of movement in a direction opposite the driving direction after the start of relative movement can be reduced and, thus, a delay in drive can be reduced.

### Second Embodiment

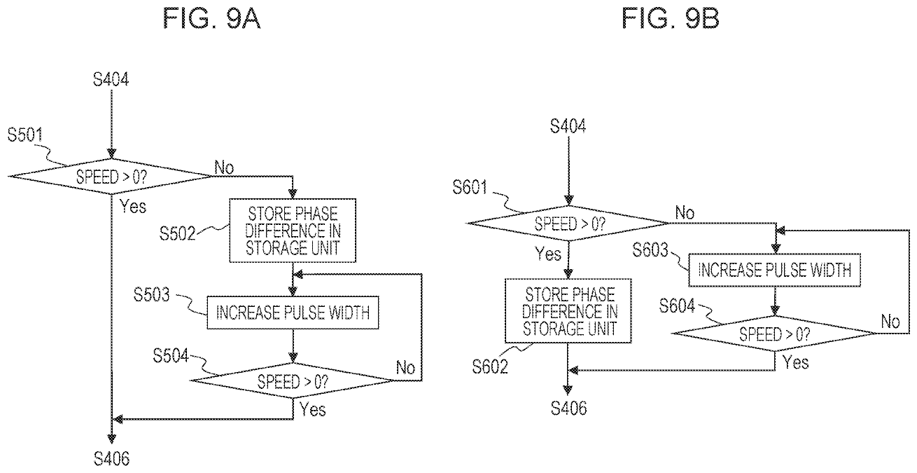

The second embodiment is described below with reference to a configuration in which, in the above-described first embodiment, the value stored in the storage unit 306 is updated using the value immediately after the start of relative movement. FIGS. 9A and 9B are flowcharts of a part of a control method for use of the control device 200 of the vibration actuator 100 according to the second embodiment. According to the second embodiment, since the process flow from step S401 to S405 and the process flow from step S406 to S415 are the same as those illustrated in FIG. 6, description of the process flows is omitted.

As illustrated in FIG. 9A, after it is determined in step S404 that relative movement has started on the basis of a change in the position or speed of the vibration actuator 100, the processing proceeds to step S501.

In step S501, the control unit 210 determines whether the speed of the vibration actuator 100 is positive. If the speed of the vibration actuator 100 is positive, the processing proceeds to step S406. If the speed of the vibration actuator 100 is not positive, the processing proceeds to step S502.

That is, if the positive/negative sign of the relative speed of the vibrating body 115 and the contacting body 111 is opposite to the positive/negative sign of the target speed, the processing proceeds to step S502. If the positive/negative sign of the relative speed of the vibrating body 115 and the contacting body 111 is the same as the positive/negative sign of the target speed, the processing proceeds to step S406.

In step S502, the control unit 210 stores the phase differences between the 2-phase AC signals in the storage unit 306. At this time, among the phase differences stored in the storage unit 306, the control unit 210 holds a first value and a second value in the storage unit 306. As used herein, the term “first value” refers to the upper limit of the first phase difference zone that is a phase difference zone in which the amplitude in the direction that intersects the driving direction is greater than the amplitude in the direction horizontal to the driving direction. The term “second value” refers to the lower limit of the second phase difference zone that is a phase difference zone in which the amplitude in the direction horizontal to the driving direction is greater than the amplitude in the direction that intersects the driving direction. The control unit 210 sets a phase difference that is greater than the first value and less than the second value as the first phase difference for the next drive. The first phase difference zone is, for example, 0° to 90°, and the second phase difference zone is, for example, 90° to 180°.

In step S503, the control unit 210 increases the pulse width of the 2-phase AC signals.

In step S504, the control unit 210 determines whether the speed of the vibration actuator 100 is positive. If the speed of the vibration actuator 100 is not positive, the processing returns to step S503, where steps S503 and S504 are repeated. If the speed of the vibration actuator 100 is positive, the processing proceeds to step S406.

As described above, in step S502, the control unit 210 functions as a saving unit. If the positive/negative sign of the relative speed of the vibrating body 115 and the contacting body 111 is opposite to the positive/negative sign of the target speed after the first period and before the second period, the control unit 210 stores the phase difference between the plurality of AC signals in the storage unit 306. In step S401 illustrated in FIG. 6, the control unit 210 sets the first phase difference on the basis of the phase difference stored in the storage unit 306.

In step S503, if the positive/negative sign of the relative speed of the vibrating body 115 and the contacting body 111 is opposite to the positive/negative sign of the target speed after the first period and before the second period, the control unit 210 performs control to increase the pulse width (or the amplitude) of the plurality of AC signals until the positive/negative signs are the same.

According to the second embodiment, the phase difference when the speed becomes negative immediately after the start of relative movement is stored, and other phase differences are defined as the first phase differences. As a variation example of the second embodiment, an embodiment is described below with reference to FIG. 9B, in which the phase difference when the speed becomes positive immediately after the start of relative movement is stored and the phase difference is defined as the first phase difference.

As illustrated in FIG. 9B, after it is determined in step S404 that relative movement has started on the basis of a change in the position or speed of the vibration actuator 100, the processing proceeds to step S601.

In step S601, the control unit 210 determines whether the speed of the vibration actuator 100 is positive. If the speed of the vibration actuator 100 is positive, the processing proceeds to step S602. If the speed of the vibration actuator 100 is not positive, the processing proceeds to step S603.

That is, if the positive/negative sign of the relative speed of the vibrating body 115 and the contacting body 111 is opposite to the positive/negative sign of the target speed, the processing proceeds to step S603. If the positive/negative sign of the relative speed of the vibrating body 115 and the contacting body 111 is the same as the positive/negative sign of the target speed, the processing proceeds to step S602.

In step S602, the control unit 210 stores the phase differences of the 2-phase AC signals in the storage unit 306. At this time, among the stored phase differences, the control unit 210 holds the upper and lower limits of the stored phase differences. The control unit 210 sets a phase difference that is greater than or equal to the lower limit and less than or equal to the upper limit of the phase differences as the first phase difference for the next drive. Thereafter, the processing proceeds to step S406.

In step S603, the control unit 210 increases the pulse width of the 2-phase AC signals. In step S604, the control unit 210 determines whether the speed of the vibration actuator 100 is positive. If the speed of the vibration actuator 100 is not positive, the processing returns to step S603, where steps S603 and S604 are repeated. If the speed of the vibration actuator 100 is positive, the processing proceeds to step S406.

As described above, in step S602, if the positive/negative sign of the relative speed of the vibrating body 115 and the contacting body 111 is the same as the positive/negative sign of the target speed after the first period and before the second period, the control unit 210 stores the phase differences of the plurality of AC signals in the storage unit 306. In step S401 illustrated in FIG. 6, the control unit 210 sets the first phase difference on the basis of the phase differences stored in the storage unit 306.

In step S603, if the positive/negative sign of the relative speed of the vibrating body 115 and the contacting body 111 is opposite to the positive/negative sign of the target speed after the first period and before the second period, the control unit 210 performs control to increase the pulse width (or the amplitude) of the plurality of AC signals until the positive/negative signs are the same.

Thus, by storing and updating the phase differences in the storage unit 306 in accordance with the positive/negative sign of the speed immediately after the start of relative movement, the phenomenon of movement in the opposite direction immediately after the start of relative movement can be reduced even if a conditional change occurs due to external factors, such as the temperature, posture, or load. This allows the transition to control using the frequency, pulse width, and phase difference between the 2-phase AC signals set on the basis of the commanded position or commanded speed, while reducing a delay in drive.

While the method for storing the phase difference immediately after the start of relative movement has been described above, the method is not limited thereto. The phenomenon of movement in the opposite direction immediately after the start of relative movement may be avoided by storing the pulse width and frequency obtained immediately after the start of relative movement and similarly setting the pulse width and frequency as the initial values for the next drive.

### Third Embodiment

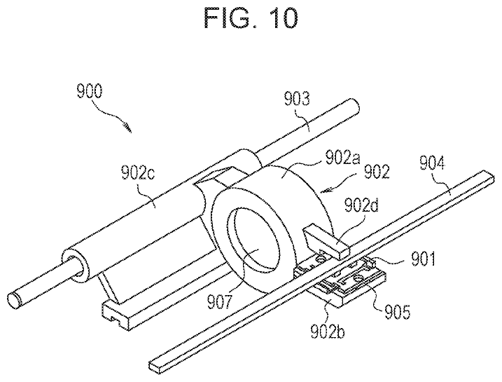

The third embodiment is described below with reference to the configuration of an image pickup apparatus (an optical apparatus) such as a camera, which is an example of an apparatus including the vibration drive system 150 according to the first or second embodiment described above. FIG. 10 is a perspective view of an example of the structure of a lens-driving mechanism unit 900 of a lens barrel. The lens-driving mechanism unit 900 includes a lens holder 902 that is an object to be driven, a vibrating body 901 that drives the lens holder 902, a pressurizing magnet 905, a first guide bar 903, a second guide bar 904, and a base (not illustrated).

The lens holder 902 includes a cylindrical body unit 902a, a holding unit 902b that holds the vibrating body 901 and the pressurizing magnet 905, a first guide unit 902c that is fitted to the first guide bar 903 to form a first guide unit, and a fall-off prevention unit 902d. The body unit 902a holds a lens 907. The first guide bar 903 and the second guide bar 904 are disposed parallel to each other, and both ends of each of the first guide bar 903 and the second guide bar 904 are fixed to the base (not illustrated).

The pressurizing magnet 905 that constitutes the pressure-applying unit is composed of a permanent magnet and two yokes disposed at either end of the permanent magnet. A magnetic circuit is formed between the pressurizing magnet 905 and the second guide bar 904, and an attractive force is generated between the members. As a result, the front ends of the two protruding portions provided on the vibrating body 901 are held pressed against the second guide bar 904 with a predetermined force and, thus, the second guide unit is formed.

The pressurizing magnet 905 is disposed at a distance from the second guide bar 904 and, thus, is not in contact with the second guide bar 904. For this reason, if the second guide unit is subjected to an external force or the like, the protruding portion of the vibrating body 901 may be separated off from the second guide bar 904. In this case, the fall-off prevention unit 902d provided on the lens holder 902 is brought into contact with the second guide bar 904, and the holding unit 902b of the lens holder 902 returns to its original position, so that the protruding portion of the vibrating body 901 is in contact with the second guide bar 904 again.

The vibrating body 901 has the same structure as the vibrating body 115 described in the first embodiment.

Therefore, by applying a predetermined AC voltage to the piezoelectric element of the vibrating body 901, elliptical vibrations are generated in the two protruding portions. Thus, a frictional driving force is generated between the vibrating body 901 and the second guide bar 904. Since the first guide bar 903 and the second guide bar 904 are fixed at this time, the generated frictional driving force can move the lens holder 902 in the length direction of the first guide bar 903 and the second guide bar 904.

While a magnetic force (the pressurizing magnet 905) is used as the pressurizing mechanism in the lens-driving mechanism unit 900, the pressurizing mechanism is not limited thereto. A spring force may be used. In addition, while the lens-driving mechanism unit 900 is configured to serve as a linear vibration drive system, the lens-driving mechanism unit is not limited thereto. A rotational vibration drive system can also be used to configure the lens-driving mechanism unit. That is, the rotational force of an object to be driven is used to rotate an annular member that holds a lens, and the amount of rotation of the annular member is converted into the amount of linear movement in the optical axis direction using a technique such as engagement of a cam pin with a cam groove. This enables the lens to move in the optical axis direction.

The driving of a lens using the vibration drive system is suitable for driving a lens for autofocusing. However, in addition to a lens for autofocusing, the same configuration can drive a lens for zooming. Furthermore, the vibration drive system can be used to drive an image sensor on which light that has passed through the lens forms an image or to drive the lens or image sensor for image stabilization.

### Other Embodiments

While the third embodiment has been described with reference to an apparatus using the vibration drive system 150, the application example of the vibration drive system 150 is not limited thereto. The vibration drive system 150 can be widely applied to electronic devices including a component that requires positioning by driving the vibration actuator 100.

While description has been made with reference to exemplary embodiments, the present disclosure is not limited to the specific embodiments, and the present disclosure includes a variety of embodiments within the spirit and scope of the embodiments. For example, the commanded position generation unit 301 generates a command value related to the position and obtains the control amount from the deviation from the detection value obtained from the position detection unit 120. However, the technique is not limited thereto. The commanded position generation unit 301 may generate a command value related to the speed and obtain the control amount from the deviation from a speed calculated from the detection value of the position detection unit 120.

The configurations (electronic devices and electrical components used) of the control unit 210 and the drive unit 220 are not limited insofar as the configuration can realize the functions described above.

While a 2-phase drive configuration in which the piezoelectric element 114 is driven in two phases has been described above for the control device 200, the control device 200 is not limited to a 2-phase drive vibration actuator, but the present disclosure can be applied to a vibration actuators that are driven by a plurality of AC voltages in three or more phases.

The present disclosure can also be implemented by supplying a program that realizes one or more functions of the above-described embodiments to a system or an apparatus via a network or a storage medium and causing one or more processors in a computer of the system or apparatus to read out and execute the program. Furthermore, the present disclosure can be implemented by a circuit (for example, an application specific integrated circuit (ASIC)) that realizes one or more of the functions.

The above-described embodiments are merely specific examples for implementing the present disclosure, and the technical scope of the present disclosure is not to be interpreted as limited by the embodiments. That is, the present disclosure can be implemented in various forms without departing from the technical spirit or main features.

The disclosure of the present embodiments includes the following configurations, methods, a program, and a non-transitory storage medium that stores the program.

### Configuration 1

A control device controls driving of a vibration actuator configured to move a vibrating body and a contacting body in contact with the vibrating body relative to each other by vibration of the vibrating body excited when a plurality of signals having a phase difference are applied to an electromechanical energy conversion element. The device includes a first control unit configured to control the phase difference between the plurality of signals to a first phase difference in a first period from when the vibrating body and the contacting body do not move relative to each other to when the vibrating body and the contacting body start moving relative to each other, a second control unit configured to control the phase difference between the plurality of signals to transition from the first phase difference to a second phase difference having an absolute value that is less than an absolute value of the first phase difference in a second period after the vibrating body and the contacting body start moving relative to each other, and a third control unit configured to control the phase difference between the plurality of signals based on one of a relative position and a relative speed of the vibrating body and the contacting body and one of a target position and a target speed in a third period after the phase difference between the plurality of signals transitions to the second phase difference.

### Configuration 2

In the control device described in Configuration 1, the first control unit performs control to increase one of a pulse width and an amplitude of the plurality of signals in the first period until the vibrating body and the contacting body start moving relative to each other, and the third control unit controls the phase difference between the plurality of signals and one of the pulse width and the amplitude of the plurality of signals based on one of the relative position and the relative speed of the vibrating body and the contacting body and one of the target position and the target speed in the third period.

### Configuration 3

In the control device described in Configuration 1 or 2, in the third period, the third control unit controls the phase difference between the plurality of signals, one of the pulse width and the amplitude of the plurality of signals, and a frequency of the plurality of signals based on one of the relative position and the relative speed of the vibrating body and the contacting body and one of the target position and the target speed.

### Configuration 4

In the control device described in any one of Configurations 1 to 3, the first phase difference is such that a positive/negative sign of one of the relative position and the relative speed of the vibrating body and the contacting body immediately after the vibrating body and the contacting body start moving relative to each other is not opposite to the positive/negative sign of one of the target position and the target speed.

### Configuration 5

In the control device described in Configuration 4, among the phase differences for which the positive/negative signs are not opposite, the first phase difference is greater than an upper limit of a phase difference zone in which, regarding an elliptical motion of a contact portion of the vibrating body, an amplitude in a direction intersecting a driving direction of the vibration actuator is greater than an amplitude in a direction horizontal to the driving direction and less than a lower limit of a phase difference zone in which the amplitude in the direction horizontal to the driving direction is greater than the amplitude in the direction intersecting the driving direction.

### Configuration 6

In the control device described in Configuration 4, the first phase difference is greater than or equal to the lower limit and less than or equal to the upper limit of the phase differences for which the positive/negative signs are not opposite.

### Configuration 7

In the control device described in any one of Configurations 1 to 6, the second phase difference is a phase difference between the plurality of signals calculated based on one of the relative position and the relative speed of the vibrating body and the contacting body and one of the target position and the target speed.

### Configuration 8

In the control device described in any one of Configurations 1 to 7, the first control unit maintains the first phase difference as the phase difference between the plurality of signals and gradually increases one of a pulse width and an amplitude of the plurality of signals in the first period.

### Configuration 9

In the control device described in any one of Configurations 1 to 8, the second control unit controls a pulse width or an amplitude of the plurality of signals so that the pulse width or the amplitude of the plurality of signals gets closer to a pulse width or an amplitude of the plurality of signals calculated based on one of the relative position and the relative speed of the vibrating body and the contacting body and one of the target position and the target speed in the second period.

### Configuration 10

In the control device described in any one of Configurations 1 to 8, the second control unit performs control to maintain or increase one of a pulse width and an amplitude of the plurality of signals in the second period.

### Configuration 11

In the control device described in any one of Configurations 1 to 10, the third control unit controls a frequency of the plurality of signals based on one of the relative position and the relative speed of the vibrating body and the contacting body and one of the target position and the target speed in the third period if the phase difference between the plurality of signals reaches one of the upper limit and the lower limit.

### Configuration 12

In the control device described in any one of Configurations 1 to 11, the third control unit controls a frequency of the plurality of signals based on one of the relative position and the relative speed of the vibrating body and the contacting body and one of the target position and the target speed in the third period if one of the pulse width and the amplitude of the plurality of signals reaches the upper limit.

### Configuration 13

The control device described in Configuration 4 further includes a saving unit configured to store the phase difference between the plurality of signals in a storage unit when the positive/negative sign of the relative speed of the vibrating body and the contacting body is opposite to the positive/negative sign of the target speed after the first period and before the second period. The first control unit sets the first phase difference based on the phase difference stored in the storage unit.

### Configuration 14

The control device described in Configuration 4 further includes a saving unit configured to store the phase difference between the plurality of signals in a storage unit when the positive/negative sign of the relative speed of the vibrating body and the contacting body is the same as the positive/negative sign of the target speed after the first period and before the second period. The first control unit sets the first phase difference based on the phase difference stored in the storage unit.

### Configuration 15

The control device described in Configuration 4 further includes a fourth control unit configured to perform control to increase one of the pulse width and the amplitude of the plurality of signals until the positive/negative sign of the relative speed of the vibrating body and the contacting body is the same as the positive/negative sign of the target speed if the positive/negative sign of the relative speed of the vibrating body and the contacting body is opposite to the positive/negative sign of the target speed after the first period and before the second period.

### Configuration 16

A control device controls driving of a vibration actuator configured to move a vibrating body and a contacting body in contact with the vibrating body relative to each other by vibration of the vibrating body excited when a plurality of signals having a phase difference are applied to an electromechanical energy conversion element. The control device includes the device includes a first control unit configured to control the phase difference between the plurality of signals to a first phase difference and start moving the vibrating body and the contacting body relative to each other when the vibrating body and the contacting body do not move relative to each other, and the first phase difference is such that a positive/negative sign of one of a relative position and a relative speed of the vibrating body and the contacting body immediately after the vibrating body and the contacting body start moving relative to each other is not opposite to a positive/negative sign of one of a target position and a target speed.

### Configuration 17

In the control device described in Configuration 16, among the phase differences for which the positive/negative signs are not opposite, the first phase difference is greater than an upper limit of a phase difference zone in which, regarding the elliptical motion of a contact portion of the vibrating body, an amplitude in a direction intersecting a driving direction of the vibration actuator is greater than an amplitude in a direction horizontal to the driving direction and less than a lower limit of a phase difference zone in which the amplitude in the direction horizontal to the driving direction is greater than the amplitude in the direction intersecting the driving direction.

### Configuration 18

In the control device described in Configuration 16, the first phase difference is greater than or equal to the lower limit and less than or equal to the upper limit of the phase differences for which the positive/negative signs are not opposite.

### Configuration 19

The control device described in any one of Configurations 16 to 18 further includes a storage unit configured to store a range of the phase difference for which the positive/negative sign of one of the relative position and the relative speed of the vibrating body and the contacting body immediately after the vibrating body and the contacting body move relative to each other is not opposite to the positive/negative sign of one of the target position and the target speed. The first control unit sets the first phase difference based on the range of the phase difference stored in the storage unit.

### Configuration 20

In the control device described in any one of Configurations 16 to 19, the first control unit performs control to set the phase difference between the plurality of signals to a first phase difference, set one of a pulse width and an amplitude of the plurality of signals to one of a first pulse width and a first amplitude when the vibrating body and the contacting body do not move relative to each other, and start moving the vibrating body and the contacting body relative to each other. The first phase difference and one of the first pulse width and the first amplitude are a phase difference and one of a pulse width and an amplitude for which the positive/negative sign of one of the relative position and the relative speed of the vibrating body and the contacting body immediately after the vibrating body and the contacting body start moving relative to each other is not opposite to the positive/negative sign of one of the target position and the target speed.

### Configuration 21

An electronic device includes the control device described in any one of Configurations 1 to 20 and the vibration actuator.

### Method 1

A method for controlling a control device is provided. The control device controls driving of a vibration actuator configured to move a vibrating body and a contacting body in contact with the vibrating body relative to each other by vibration of the vibrating body excited when a plurality of signals having a phase difference are applied to an electromechanical energy conversion element. The method includes performing control to set the phase difference between the plurality of signals to a first phase difference in a first period from when the vibrating body and the contacting body do not move relative to each other to when the vibrating body and the contacting body start moving relative to each other, controlling the phase difference between the plurality of signals to transition from the first phase difference to a second phase difference having an absolute value that is less than an absolute value of the first phase difference in a second period after the vibrating body and the contacting body start moving relative to each other, and controlling the phase difference between the plurality of signals based on one of a relative position and a relative speed of the vibrating body and the contacting body and one of a target position and a target speed in a third period after the phase difference between the plurality of signals transitions to the second phase difference.

### Method 2

A method for controlling a control device is provided. The control device controls driving of a vibration actuator configured to move a vibrating body and a contacting body in contact with the vibrating body relative to each other by vibration of the vibrating body excited when a plurality of signals having a phase difference are applied to an electromechanical energy conversion element. The method includes performing control to set the phase difference between the plurality of signals to a first phase difference when the vibrating body and the contacting body do not move relative to each other and start moving the vibrating body and the contacting body relative to each other. The first phase difference is such that a positive/negative sign of one of a relative position and a relative speed of the vibrating body and the contacting body immediately after the vibrating body and the contacting body start moving relative to each other is not opposite to a positive/negative sign of one of a target position and a target speed.

### Program 1

A storage medium stores a program for causing a computer to function as the control device described in any one of Configurations 1 to 20.

According to the present disclosure, a delay in the relative movement of the vibrating body and the contacting body can be reduced.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-036395 filed Mar. 9, 2023, which is hereby incorporated by reference herein in its entirety.

What is claimed is:

1. A control device for controlling driving of a vibration actuator configured to move a vibrating body and a contacting body in contact with the vibrating body relative to each other by vibration of the vibrating body excited when a plurality of signals having a phase difference are applied to an electromechanical energy conversion element, the device comprising:
a first control unit configured to control the phase difference between the plurality of signals to a first phase difference in a first period from when the vibrating body and the contacting body do not move relative to each other to when the vibrating body and the contacting body start moving relative to each other;
a second control unit configured to control the phase difference between the plurality of signals to transition from the first phase difference to a second phase difference having an absolute value that is less than an absolute value of the first phase difference in a second period after the vibrating body and the contacting body start moving relative to each other; and
a third control unit configured to control the phase difference between the plurality of signals based on one of a relative position and a relative speed of the vibrating body and the contacting body and one of a target position and a target speed in a third period after the phase difference between the plurality of signals transitions to the second phase difference.

2. The control device according to claim 1, wherein the first control unit performs control to increase one of a pulse width and an amplitude of the plurality of signals in the first period until the vibrating body and the contacting body start moving relative to each other, and
wherein the third control unit controls the phase difference between the plurality of signals and one of the pulse width and the amplitude of the plurality of signals based on one of the relative position and the relative speed of the vibrating body and the contacting body and one of the target position and the target speed in the third period.

3. The control device according to claim 1, wherein, in the third period, the third control unit controls the phase difference between the plurality of signals, one of a pulse width and an amplitude of the plurality of signals, and a frequency of the plurality of signals based on one of the relative position and the relative speed of the vibrating body and the contacting body and one of the target position and the target speed.

4. The control device according to claim 1, wherein the first phase difference is such that a positive/negative sign of one of the relative position and the relative speed of the vibrating body and the contacting body immediately after the vibrating body and the contacting body start moving relative to each other is not opposite to the positive/negative sign of one of the target position and the target speed.

5. The control device according to claim 4, wherein, among the phase differences for which the positive/negative signs are not opposite, the first phase difference is greater than an upper limit of a phase difference zone in which, regarding an elliptical motion of a contact portion of the vibrating body, an amplitude in a direction intersecting a driving direction of the vibration actuator is greater than an amplitude in a direction horizontal to the driving direction and less than a lower limit of a phase difference zone in which the amplitude in the direction horizontal to the driving direction is greater than the amplitude in the direction intersecting the driving direction.

6. The control device according to claim 4, wherein the first phase difference is greater than or equal to a lower limit and less than or equal to an upper limit of the phase differences for which the positive/negative signs are not opposite.

7. The control device according to claim 1, wherein the second phase difference is a phase difference between the plurality of signals calculated based on one of the relative position and the relative speed of the vibrating body and the contacting body and one of the target position and the target speed.

8. The control device according to claim 1, wherein the first control unit maintains the first phase difference as the phase difference between the plurality of signals and gradually increases one of a pulse width and an amplitude of the plurality of signals in the first period.

9. The control device according to claim 1, wherein the second control unit controls a pulse width or an amplitude of the plurality of signals so that the pulse width or the amplitude of the plurality of signals gets closer to a pulse width or an amplitude of the plurality of signals calculated based on one of the relative position and the relative speed of the vibrating body and the contacting body and one of the target position and the target speed in the second period.

10. The control device according to claim 1, wherein the second control unit performs control so as to maintain or increase one of a pulse width and an amplitude of the plurality of signals in the second period.

11. The control device according to claim 1, wherein the third control unit controls a frequency of the plurality of signals based on one of the relative position and the relative speed of the vibrating body and the contacting body and one of the target position and the target speed in the third period if the phase difference between the plurality of signals reaches one of an upper limit and a lower limit.

12. The control device according to claim 1, wherein the third control unit controls a frequency of the plurality of signals based on one of the relative position and the relative speed of the vibrating body and the contacting body and one of the target position and the target speed in the third period if one of a pulse width and an amplitude of the plurality of signals reaches an upper limit.

13. The control device according to claim 4, further comprising:
a saving unit configured to store the phase difference between the plurality of signals in a storage unit when the positive/negative sign of the relative speed of the vibrating body and the contacting body is opposite to the positive/negative sign of the target speed after the first period and before the second period,
wherein the first control unit sets the first phase difference based on the phase difference stored in the storage unit.

14. The control device according to claim 4, further comprising:
a saving unit configured to store the phase difference between the plurality of signals in a storage unit when the positive/negative sign of the relative speed of the vibrating body and the contacting body is the same as the positive/negative sign of the target speed after the first period and before the second period,
wherein the first control unit sets the first phase difference based on the phase difference stored in the storage unit.

15. The control device according to claim 4, further comprising:
a fourth control unit configured to perform control to increase one of a pulse width and an amplitude of the plurality of signals until the positive/negative sign of the relative speed of the vibrating body and the contacting body is the same as the positive/negative sign of the target speed if the positive/negative sign of the relative speed of the vibrating body and the contacting body is opposite to the positive/negative sign of the target speed after the first period and before the second period.

16. A control device for controlling driving of a vibration actuator configured to move a vibrating body and a contacting body in contact with the vibrating body relative to each other by vibration of the vibrating body excited when a plurality of signals having a phase difference are applied to an electromechanical energy conversion element, the device comprising:
a first control unit configured to control the phase difference between the plurality of signals to a first phase difference and start moving the vibrating body and the contacting body relative to each other when the vibrating body and the contacting body do not move relative to each other,
wherein the first phase difference is such that a positive/negative sign of one of a relative position and a relative speed of the vibrating body and the contacting body immediately after the vibrating body and the contacting body start moving relative to each other is not opposite to a positive/negative sign of one of a target position and a target speed.

17. The control device according to claim 16, wherein, among the phase differences for which the positive/negative signs are not opposite, the first phase difference is greater than an upper limit of a phase difference zone in which, regarding an elliptical motion of a contact portion of the vibrating body, an amplitude in a direction intersecting a driving direction of the vibration actuator is greater than an amplitude in a direction horizontal to the driving direction and less than a lower limit of a phase difference zone in which the amplitude in the direction horizontal to the driving direction is greater than the amplitude in the direction intersecting the driving direction.

18. The control device according to claim 16, wherein the first phase difference is greater than or equal to the lower limit and less than or equal to an upper limit of the phase differences for which the positive/negative signs are not opposite.

19. The control device according to claim 16, further comprising:
a storage unit configured to store a range of the phase difference for which the positive/negative sign of one of the relative position and the relative speed of the vibrating body and the contacting body immediately after the vibrating body and the contacting body move relative to each other is not opposite to the positive/negative sign of one of the target position and the target speed,
wherein the first control unit sets the first phase difference based on the range of the phase difference stored in the storage unit.

20. The control device according to claim 16, wherein the first control unit performs control to set the phase difference between the plurality of signals to a first phase difference, set one of a pulse width and an amplitude of the plurality of signals to one of a first pulse width and a first amplitude when the vibrating body and the contacting body do not move relative to each other, and start moving the vibrating body and the contacting body relative to each other, and
wherein the first phase difference and one of the first pulse width and the first amplitude are a phase difference and one of a pulse width and an amplitude for which the positive/negative sign of one of the relative position and the relative speed of the vibrating body and the contacting body immediately after the vibrating body and the contacting body start moving relative to each other is not opposite to the positive/negative sign of one of the target position and the target speed.

21. An electronic device comprising:
a control device; and
a vibration actuator configured to move a vibrating body and a contacting body in contact with the vibrating body relative to each other by vibration of the vibrating body excited when a plurality of signals having a phase difference are applied to an electromechanical energy conversion element,
wherein the control device controls driving of the vibration actuator, and
wherein the control device comprises a first control unit configured to control the phase difference between the plurality of signals to a first phase difference in a first period from when the vibrating body and the contacting body do not move relative to each other to when the vibrating body and the contacting body start moving relative to each other, a second control unit configured to control the phase difference between the plurality of signals to transition from the first phase difference to a second phase difference having an absolute value that is less than an absolute value of the first phase difference in a second period after the vibrating body and the contacting body start moving relative to each other, and a third control unit configured to control the phase difference between the plurality of signals based on one of a relative position and a relative speed of the vibrating body and the contacting body and one of a target position and a target speed in a third period after the phase difference between the plurality of signals transitions to the second phase difference.

22. A method for controlling a control device wherein the control device controls driving of a vibration actuator configured to move a vibrating body and a contacting body in contact with the vibrating body relative to each other by vibration of the vibrating body excited when a plurality of signals having a phase difference are applied to an electromechanical energy conversion element, the method comprising:
performing control to set the phase difference between the plurality of signals to a first phase difference in a first period from when the vibrating body and the contacting body do not move relative to each other to when the vibrating body and the contacting body start moving relative to each other;
controlling the phase difference between the plurality of signals to transition from the first phase difference to a second phase difference having an absolute value that is less than an absolute value of the first phase difference in a second period after the vibrating body and the contacting body start moving relative to each other; and
controlling the phase difference between the plurality of signals based on one of a relative position and a relative speed of the vibrating body and the contacting body and one of a target position and a target speed in a third period after the phase difference between the plurality of signals transitions to the second phase difference.

23. A method for controlling a control device wherein the control device controls driving of a vibration actuator configured to move a vibrating body and a contacting body in contact with the vibrating body relative to each other by vibration of the vibrating body excited when a plurality of signals having a phase difference are applied to an electromechanical energy conversion element, the method comprising:
performing control to set the phase difference between the plurality of signals to a first phase difference when the vibrating body and the contacting body do not move relative to each other and start moving the vibrating body and the contacting body relative to each other,
wherein the first phase difference is such that a positive/negative sign of one of the relative position and the relative speed of the vibrating body and the contacting body immediately after the vibrating body and the contacting body start moving relative to each other is not opposite to a positive/negative sign of one of a target position and a target speed.

24. A non-transitory computer-readable storage medium storing a program for causing a computer to execute a method for controlling a control device wherein the control device controls driving of a vibration actuator configured to move a vibrating body and a contacting body in contact with the vibrating body relative to each other by vibration of the vibrating body excited when a plurality of signals having a phase difference are applied to an electromechanical energy conversion element, the method comprising:
performing control to set the phase difference between the plurality of signals to a first phase difference in a first period from when the vibrating body and the contacting body do not move relative to each other to when the vibrating body and the contacting body start moving relative to each other;
controlling the phase difference between the plurality of signals to transition from the first phase difference to a second phase difference having an absolute value that is less than an absolute value of the first phase difference in a second period after the vibrating body and the contacting body start moving relative to each other; and
controlling the phase difference between the plurality of signals based on one of a relative position and a relative speed of the vibrating body and the contacting body and one of a target position and a target speed in a third period after the phase difference between the plurality of signals transitions to the second phase difference.
